(19) United States
(12) Patent Application Publication
(10) Pub. No.: US 2026/0247683 A1
(43) Pub. Date: Aug. 20, 2026

(54) METHOD OF FORMING A RECESSED GATE TERMINAL, AND WAFER INCLUDING THE RECESSED GATE TERMINAL AND HAVING REDUCED WARPAGE

(71) Applicant: STMicroelectronics International N.V., Geneva (CH)

(72) Inventors: Simone Dario MARIANI, Vedano Al Lambro (IT); Isabelle THOMAS-BOUTHERIN, La Tronche (FR); Davide FAGIANI, Sorisole (IT); Mario Francesco PISTONI, Milan (IT); Manuel ISACCHI, Busnago (IT); Julien BOUVIER, Grenoble (FR)

(73) Assignee: STMicroelectronics International N.V., Geneva (CH)

(21) Appl. No.: 19/534,013

(22) Filed: Feb. 9, 2026

(30) Foreign Application Priority Data
Feb. 18, 2025 (IT) 102025000003174

(51) Int. Cl. H10D 64/27; H10D 12/00; H10D 64/01; H10D 64/66

(52) U.S. Cl. CPC H10D 64/518; H10D 12/481; H10D 64/01306; H10D 64/01324; H10D 64/513; H10D 64/662

(57) ABSTRACT

The proposed solution is designed for IGBT and discrete devices with vertical gate; the proposed method includes: trench formation, including lithography and etching, in a wafer; oxidation to grow gate dielectric; polysilicon filling with a thin layer to form first gate conductive layer; a second dielectric deposition and recession to fill half of the trench from the bottom up to a fixed depth; trench filling with polysilicon to form a second gate conductive layer. The second dielectric can be chosen with a dedicated stress and a dedicated recession, to counterbalance the polysilicon stress and reduce wafer warpage.

### BACKGROUND

### Technical Field

The present disclosure relates to a method of forming a trench-gate terminal of an electronic device and a wafer or die including the trench-gate terminal.

### Description of the Related Art

IGBTs (Insulated-Gate Bipolar Transistors), as well as other discrete devices with vertical conductive channel, typically use a trench-based design for the gate region or terminal. The bottom and lateral walls of the trenches are usually covered with an oxide layer having substantially uniform thickness, and the trench is then filled with polysilicon, so that the polysilicon is isolated from the substrate by the oxide layer. The oxide is the gate dielectric and the polysilicon is the gate conductive plate.

Trenches often cover most of the die area, providing a high Mask Transmission Factor (around 30%) for the corresponding mask level. The Mask Transmission Factor is the percentage of the mask where the photoresist is removed, corresponding to the area where the trenches are etched.

Give the relatively high coverage of the die area, the gate oxide and, more in particular, the polysilicon, generate a stress that causes, during manufacturing, wafer deformation; moreover, the deformation is usually asymmetrical (in top-side view, the wafer deformation along orthogonal directions, X-Y, is not symmetrical). The manufacturing tools used to handle and process the wafers have a limited capacity to manage deformed wafers.

Furthermore, for wafers of about 300 mm of diameter (or even 200mm or lower), the bow is worsened by geometrical factors, while the bow acceptance range of manufacturing tools remains almost unchanged; handling problems and the risks of scrapping wafers and/or damaging the tools are higher.

In the art known to the Applicant, warpage or bowing can be managed by dividing the polysilicon deposition into a plurality of deposition steps, with a thermal treatment after each deposition step (typically an RTP). A warpage or bowing compensation can also include a dedicated layer deposition at the backside of the wafer, to counterbalance the stress.

However, these solutions have some drawbacks, including for example the necessity of multiple polysilicon depositions and thermal treatments, which cause increased manufacturing costs and slower the manufacturing process. Moreover, the deposition of a backside layer requires dedicated tools, and the deposited backside layer typically suffers during high thermal budgets. Moreover, the latter solution does not address the issue of asymmetrical warpage or bowing along X and Y directions.

For the above reasons, there is the need of providing alternative approaches of trench manufacturing that minimize the generated stress.

### BRIEF SUMMARY

According to the present disclosure, a method of forming a gate terminal of an electronic device and a wafer or die including the gate are provided.

The method includes, in part, trench formation, including lithography and etching, in a wafer; oxidation to grow gate dielectric; polysilicon filling with a thin layer to form first gate conductive layer; a second dielectric deposition and recession to fill half of the trench from the bottom up to a fixed depth; and trench filling with polysilicon to form a second gate conductive layer. The second dielectric can be chosen with a dedicated stress and a dedicated recession, to counterbalance the polysilicon stress and reduce wafer warpage

### BRIEF DESCRIPTION OF THE SEVERAL VIEWS OF THE DRAWINGS

For a better understanding of the present disclosure, various embodiments thereof will now be described purely by way of non-limiting example with reference to the appended drawings, wherein:

FIGS. 1A, 1B, 1C, 1D, 1E, and 1F illustrate, in lateral view, process steps to manufacture a trench according to an aspect of the present disclosure; and

FIG. 2 illustrates, by means of a flow chart, process steps of FIGS. 1A-1F.

### DETAILED DESCRIPTION

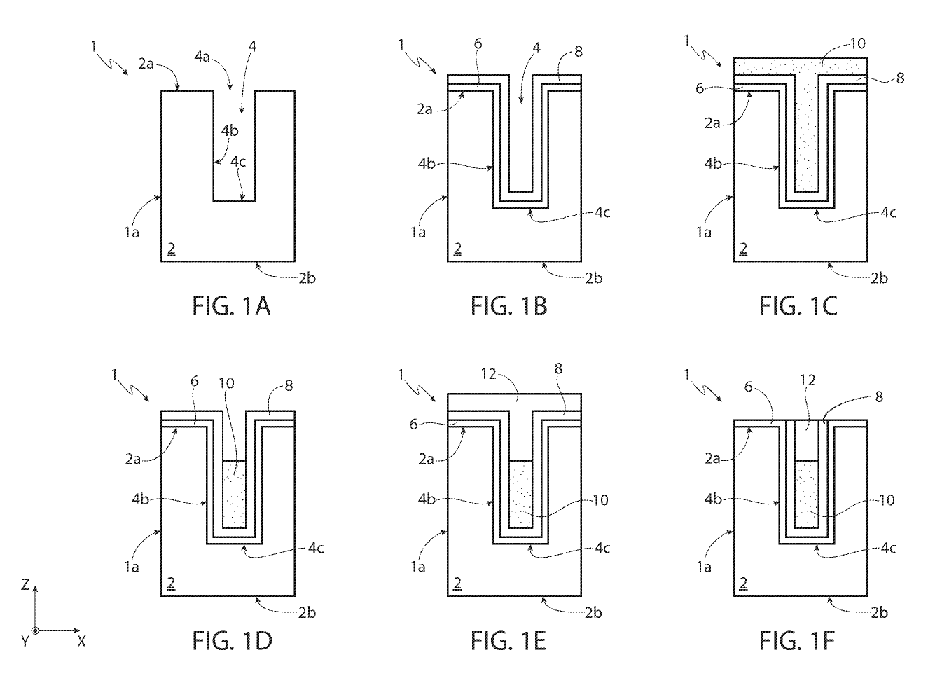

FIGS. 1A-1F show, in lateral view, a portion 1a of a wafer or a die 1, limited to the features useful to understand the present disclosure. The view of FIGS. 1A-1F is in a triaxial coordinate system of mutually orthogonal axes X, Y, Z. The wafer has, in one example, a 300 mm diameter. The wafer may also be of 200 mm of diameter, or even lower diameter according to the manufacturing technology.

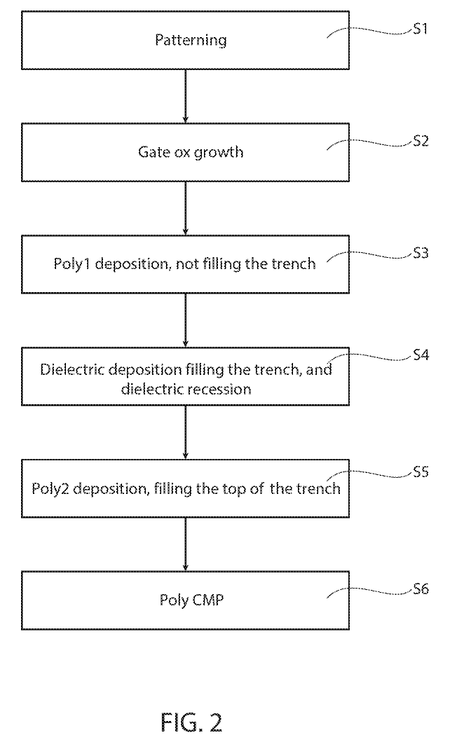

FIG. 2 is a flow chart of the process steps of FIGS. 1A-1F.

With reference to FIG. 1A, the die 1 comprises a solid body 2 of semiconductor material; for example the solid body 2 is a semiconductor substrate; alternatively the solid body 2 comprises a semiconductor substrate over which one or more epitaxial layers are grown. The semiconductor material is or includes, for example, silicon or silicon carbide.

The solid body 2 comprises a first surface 2a and a second surface 2b. The first and the second surfaces 2a, 2b are, for example, parallel to the XY plane and delimit opposite surfaces of the solid body 2 (opposite to one another along the axis Z).

A trench 4 is formed (step S1 in FIG. 2) in the solid body 2 at the first surface 2a towards the second surface 2b (along the direction of the axis Z), ending within the solid body 2 (without reaching the second surface 2b). The trench 4 can be formed by lithographic and etching techniques.

A front opening 4a of the trench 4 is coplanar with the first surface 2a. The trench 4 has a lateral wall or surface 4b and a bottom wall or surface 4c. The front opening 4a has, in top-plan view (on plane XY) a shape designed according to, for example, the needs, that is depending upon functional requirements. For example, the front opening 4a has, in top-plan view, an elongated shape substantially rectangular, with main dimension along the Y direction. The trench 4 has a depth, along the Z-axis direction, in the range 3-6 µm, for example between 4 and 5 µm. The trench 4 has a dimension, along the X-axis direction, in the range of 0.3-1.5 µm. The trench 4 has a dimension, along the Y-axis direction, for example comprised between 1 mm and 10 mm, in particular comprised between 2 mm and 6 mm.

With reference to FIG. 1B and step S2 in FIG. 2, a gate dielectric layer 6 is formed within the trench 4, covering the lateral wall 4b and the bottom wall 4c. In particular, the gate dielectric layer 6 uniformly covers the lateral wall 4b and the bottom wall 4c, with structural continuity. The gate dielectric layer 6 further extends on the first surface 2a of the solid body 2, laterally to the trench opening 4a. The gate dielectric layer 6 can be of any dielectric or electrically-insulating material, for example of silicon oxide (SiO₂). The gate dielectric layer 6 has a thickness in the range of 50-300nm (for example measured along the X direction at the lateral wall 4b, or along the Z direction at the bottom wall 4c). The gate dielectric layer 6 is for example deposited by CVD or is thermally grown by a corresponding thermal process.

Then, FIG. 1B and step S3 in FIG. 2, a first gate conductive layer 8 is formed within the trench 4 on the gate dielectric layer 6. The first gate conductive layer 8 extends at the lateral wall 4b and bottom wall 4c of the trench 4 and is electrically insulated, and physically separated, from the lateral and bottom walls 4b, 4c of the trench 4 by the gate dielectric layer 6. The first gate conductive layer 8 extends with physical and structural continuity on the gate dielectric layer 6 and has a thickness in the range 50-400nm (for example measured along the X direction at the lateral wall 4b, or along the Z direction at the bottom wall 4c). The first gate conductive layer 8 is for example of polysilicon material, with a concentration of dopant species comprised between 1x10¹⁹ at/cm³ and 1x10²¹ at/cm³.

Optionally, the first gate conductive layer 8 further extends on the first surface 2a, laterally to the trench opening 4a and on the gate dielectric layer 4.

It is noted that the first gate conductive layer 8 does not completely fill the trench 4, but leaves an empty space within the trench 4.

With reference to FIG. 1C and step S4 of FIG. 2, the trench 4 is filled with a dielectric or insulating material (for example, silicon oxide, SiO₂, or silicon nitride, SiN or Si₃N₄, or a combination of silicon oxide and silicon nitride), forming a filling layer 10. The filling layer 10 is formed on the first gate conductive layer 8 and completely fills the trench 4. Optionally, the filling layer 10 further extends above the first surface 2a of the solid body, laterally to the trench 4. The filling layer 10 is formed by depositing the dielectric or insulating material with sputtering or CVD techniques, or other techniques available in the art.

Then, FIG. 1D and step S4 of FIG. 2, a step is carried out to partially etch the filling layer 10, thus removing the filling layer 10 from part of the trench 4 and, when present, from above the first surface 2a. The etching step is for example carried out through a wet etching solution (wet etching, for example including HF in case of SiO₂ or H₃PO₄ in case of SiN/Si₃N₄) or alternatively is carried out by dry etching techniques. The etching is, for example, of isotropic type. The filling layer 10 is removed from the trench 4 starting from the front opening 4a and proceeds towards the Z axis until a certain depth is reached, for example to remove the filling layer 10 up to, or less than, half of the depth of the trench. In other terms, after the etching is completed, the filling layer 10 remains in the trench 4 at the bottom wall 4c and uniformly fills part of the trench 4 above the bottom wall 4c. In general terms, the filling layer 10 fills a percentage ranging from 40% to 80% (more particularly from 50% to 70%) of the empty space that the trench 4 has in the process step of FIG. 2 (i.e., after formation of the first gate conductive layer 8).

In one embodiment, the filling layer 10 uniformly fills at least half (50%), preferably 70-80%, of the trench 4, starting from the bottom wall 4c.

In particular, for all the embodiments disclosed, the filling layer 10 is uniform within the trench 4, meaning that there are no apertures or holes or buried cavities within the filling layer 10.

In one alternative embodiment, the formation of the filling layer 10 comprises depositing the dielectric or insulating material until the desired thickness of the filling layer 10 is reached within the trench, without performing the etching step for recessing the filling layer 10.

Then, FIG. 1E and step S5 of FIG. 2, a second gate conductive layer 12 is deposited within the trench 4, to completely fill the trench 4, above the filling layer 10. Optionally, the second gate conductive layer 12 further extends above the first surface 2a of the solid body 2, laterally to the trench opening 4a. The second gate conductive layer 12 is for example of polysilicon, N-type doped with a concentration of dopant species comprised between 1x10¹⁹ at/cm³ and 1x10²¹ at/cm³.

Then, FIG. 1F and step S6 of FIG. 2, a polishing step (e.g., by CMP, Chemical Mechanical Polishing) is carried out to completely remove, when present, the portions of the first and the second gate conductive layers 8, 12 extending on the first surface 2a of the solid body 2. The second gate conductive layer 12 therefore fills the trench 4 above the filling layer 10 and, at the aperture 4a, is coplanar with the gate dielectric layer extending on the first surface 2a laterally to the trench opening 4a and the first gate conductive layer 8 at the aperture 4a.

In one embodiment, the filling layer 10 has a dimension, along the Z axis, that is 1/5 of the empty space that the trench 4 has in the process step of FIG. 2. In another embodiment, the filling layer 10 has a dimension, along the Z axis, that is 1/2 of the empty space that the trench 4 has in the process step of FIG. 2. In another embodiment, the filling layer 10 has a dimension, along the Z axis, that is 1/1.25 of the empty space that the trench 4 has in the process step of FIG. 2.

As an example, for a trench 4 having a dimension (at process step of FIG. 1), along the Z axis, of about 4.7 µm, the filling layer 10 has a dimension, along the Z axis, ranging from 0.95 µm and 3.8 µm.

The various embodiments of the present disclosure can be used to manufacture a recessed gate terminal of an electronic device with vertical conduction, i.e., with conductive channel mainly along the Z-axis direction. Such electronic device has, as known in the art, a source terminal at the first surface 2a and a drain terminal at the second surface 2b (or vice versa). The doping of the solid body 2 may be of N-type or P-type, according to the design of the device. Accordingly, also the doping type of the first and second polysilicon layers 8, 12 can be opposite from what previously described, based on the conductive type (N or P) of the conductive channel.

The electronic device is, for example, one among: MOS transistor IC,BCD,IGBT, HV and LV discretes, VI power.

From what has been described above, the advantages of the various embodiments of the present disclosure emerge clearly.

In particular, wafer warpage or bowing is customizable by designing the filling layer 10 in terms of material and recession depth; moreover, the costs are reduced with respect to the know process steps.

A method of forming a trench-gate terminal of an electronic device, is summarized as including the steps of: forming (S1), at a first side (2a) of a solid body (2), a trench (4), the trench extending from the first side (2a) towards a direction (Z); forming (S2), within the trench (4), a gate dielectric layer (4) that covers with structural continuity lateral and bottom walls (4b, 4c) of the trench (4); forming (S3), within the trench (4) and on the gate dielectric layer (4), a first gate conductive layer (8) that extends with structural continuity along the lateral wall (4b) up to the first surface; forming (S4), within the trench (4) and on the first gate conductive layer (8), a filling layer (10) that partially fills the trench (4) from the bottom wall (4c) towards the first side (2a); and forming (S5, S6), within the trench (4) and on the filling layer (10), a second gate conductive layer (12).

The second gate conductive layer (12) is formed in direct electrical contact with the first gate conductive layer (8) above the filling layer (10).

The filling layer (10) is separated from the bottom wall (4c) of the trench exclusively by the first gate conductive layer (8) and the gate dielectric layer (4).

The filling layer (10) fills from 20% to 80%, in particular from 50% to 80%, of empty space left in the trench after the step of forming the first gate conductive layer (8).

Within the trench (4), the quantity of the filling layer (10) is one among: five times the quantity of the second gate conductive layer (12); two times the quantity of the second gate conductive layer (12); 1.25 times the quantity of the second gate conductive layer (12).

The filling layer (10) is of silicon oxide or of silicon nitride or of a combination of silicon oxide and silicon nitride.

The first and the second gate conductive layer (8, 12) are of doped polysilicon.

A wafer or die is summarized as including: a solid body (2) having a first side (2a) and a second side (2b) opposite to one another along a direction (Z); a trench (4) extending in the solid body (2) from the first side (2a) towards the second side (2b), ending within the solid body (2); a gate dielectric layer (4) in the trench (4), covering with structural continuity lateral and bottom walls (4b, 4c) of the trench (4); a first gate conductive layer (8) in the trench (4) on the gate dielectric layer (4), extending with structural continuity along the lateral wall (4b) up to the first surface (2a); a filling layer (10) in the trench (4) on the first gate conductive layer (8), that partially fills the trench (4) from the bottom wall (4c) towards the first side (2a); and a second gate conductive layer (12) in the trench (4) on the filling layer (10).

The second gate conductive layer (12) is in direct electrical contact with the first gate conductive layer (8) above the filling layer (10).

The filling layer (10) is separated from the bottom wall (4c) of the trench exclusively by the first gate conductive layer (8) and the gate dielectric layer (4).

The second gate conductive layer (12) fills the trench (4) up to the first side (2a).

The filling layer (10) is separated from the bottom wall (4c) of the trench exclusively by the first gate conductive layer (8) and the gate dielectric layer (4).

In the trench (4), the proportion of the amount of the filling layer (10) with respect to the second gate conductive layer (12) is in the range from 20% to 80%, more particularly from 50% to 80%.

Within the trench (4), the quantity of the filling layer (10) is one among: five times the quantity of the second gate conductive layer (12); two times the quantity of the second gate conductive layer (12); 1.25 times the quantity of the second gate conductive layer (12).

The filling layer (10) is of silicon nitride, or of silicon oxide, or of a combination of silicon oxide and silicon nitride; and the first and the second gate conductive layer (8, 12) are of doped polysilicon.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of forming a trench-gate terminal of an electronic device, the method comprising:
forming, at a first side of a solid body, a trench, the trench extending from the first side towards a direction;
forming, within the trench, a gate dielectric layer that covers with structural continuity lateral and bottom walls of the trench;
forming, within the trench and on the gate dielectric layer, a first gate conductive layer that extends with structural continuity along the lateral wall up to the first side;
forming, within the trench and on the first gate conductive layer, a filling layer that partially fills the trench from the bottom wall towards the first side; and
forming, within the trench and on the filling layer, a second gate conductive layer.

2. The method of claim 1, wherein the second gate conductive layer is formed in direct electrical contact with the first gate conductive layer above the filling layer.

3. The method of claim 1, wherein the filling layer is separated from the bottom wall of the trench exclusively by the first gate conductive layer and the gate dielectric layer.

4. The method of claim 1, wherein the filling layer fills from 20% to 80% of empty space left in the trench after the forming of the first gate conductive layer.

5. The method of claim 4, wherein the filling layer fills from 50% to 80% of the empty space left in the trench after the forming of the first gate conductive layer.

6. The method of claim 1, wherein, within the trench, the quantity of the filling layer is five times the quantity of the second gate conductive layer, two times the quantity of the second gate conductive layer, or 1.25 times the quantity of the second gate conductive layer.

7. The method of claim 1, wherein the filling layer includes silicon oxide, silicon nitride, or of a combination of silicon oxide and silicon nitride.

8. The method of claim 1, wherein the first and the second gate conductive layers include doped polysilicon.

9. A wafer or die comprising:
a solid body having a first side and a second side opposite to one another along a direction;
a trench extending in the solid body from the first side towards the second side, ending within the solid body;
a gate dielectric layer in the trench and covering with structural continuity lateral and bottom walls of the trench;
a first gate conductive layer in the trench, on the gate dielectric layer, and extending with structural continuity along the lateral wall up to the first side;
a filling layer in the trench and on the first gate conductive layer, the filling layer partially fills the trench from the bottom wall towards the first side; and
a second gate conductive layer in the trench and on the filling layer.

10. The wafer or die of claim 9, wherein the second gate conductive layer is in direct electrical contact with the first gate conductive layer above the filling layer.

11. The wafer or die of claim 9, wherein the filling layer is separated from the bottom wall of the trench exclusively by the first gate conductive layer and the gate dielectric layer.

12. The wafer or die of claim 9, wherein the second gate conductive layer fills the trench up to the first side.

13. The wafer or die of claim 9, wherein the filling layer is separated from the bottom wall of the trench exclusively by the first gate conductive layer and the gate dielectric layer.

14. The wafer or die of claim 9, wherein, in the trench, the proportion of the amount of the filling layer with respect to the second gate conductive layer is in the range from 20% to 80%.

15. The wafer or die claim 14, wherein, in the trench, the proportion of the amount of the filling layer with respect to the second gate conductive layer is in the range from 50% to 80%.

16. The wafer or die of claim 9, wherein, within the trench, the quantity of the filling layer is five times the quantity of the second gate conductive layer, two times the quantity of the second gate conductive layer, or 1.25 times the quantity of the second gate conductive layer.

17. The wafer or die of claim 9, wherein:
the filling layer includes silicon nitride, silicon oxide, or a combination of silicon oxide and silicon nitride; and
the first and the second gate conductive layer include doped polysilicon.

18. A method, comprising:
forming a trench in a first surface of a solid body, the trench having a lateral surface and a bottom surface;
forming a gate dielectric layer on the first surface, the lateral surface, and the bottom surface;
forming a first gate conductive layer on the gate dielectric layer, the first gate conductive layer being spaced from the first surface, the lateral surface, and the bottom surface by the gate dielectric layer;
forming a filling layer on the first gate conductive layer, the filling layer being spaced from the lateral surface and the bottom surface by the first gate conductive layer and the gate dielectric layer, the filling layer filling a first portion of the trench; and
forming a second gate conductive layer on the filling layer, the second gate conductive layer being spaced from the lateral surface by the first gate conductive layer and the gate dielectric layer, the second gate conductive layer being spaced from the bottom surface by the first gate conductive layer, the gate dielectric layer, and the filling layer, the second gate conductive layer filling a second portion of the trench.

19. The method of claim 18, wherein the forming of the filling layer includes:
forming the filling layer on the first surface, the filling layer being spaced from the first surface by the first gate conductive layer and the gate dielectric layer; and
removing a first portion of the filling layer that is on the first surface and a second portion of the filling layer that is in the trench.

20. The method of claim 19, wherein the forming of the second gate conductive layer includes:
forming the second gate conductive layer on the first surface, the second gate conductive layer being spaced from the first surface by the first gate conductive layer and the gate dielectric layer; and
removing a first portion of the second gate conductive layer that is on the first surface and a second portion of the second gate conductive layer that directly overlies the trench.
